(19) United States
(12) Patent Application Publication
(10) Pub. No.: US 2019/0182980 A1
(43) Pub. Date: Jun. 13, 2019

(54) SERVER RACK PLACEMENT IN A DATA CENTER

(71) Applicant: Facebook, Inc., Menlo Park, CA (US)

(72) Inventors: Hongzhong Jia, Cupertino, CA (US); Yusuf Abdulghani, Fremont, CA (US); Parth M. Malani, San Jose, CA (US)

(21) Appl. No.: 15/835,334

(22) Filed: Dec. 7, 2017

(51) Int. Cl. H05K 7/14; H05K 7/20; H04L 29/08; H04L 29/06

(52) U.S. Cl. CPC H05K 7/1492; H05K 7/20836; G06F 17/30575; H04L 65/403; H04L 67/1021; H04L 67/02

(57) ABSTRACT

The disclosure is directed to placement of server racks of different types in a data center for efficient allocation of resources to the servers. A data center has limited physical resources (e.g., electrical power, cooling, airflow, network bandwidth, weight capacity, etc.). Various server rack types (e.g., hosting a type of a server computer) consume different amounts of these resources. If the distribution of server rack types in a data center is imbalanced, various unexpected failures can occur. The systems considers resource utilizations of all server rack types and generates a deployment layout that assigns these server rack types across multiple rows of the data center to ensure a deployment constraint of the data center is satisfied. Application services that are run on these racks are bucketed based on their resource consumption. Each bucket is distributed in a similar manner as the rack type across the data center.

### BACKGROUND

A data center is a facility used to house computer systems and associated components, such as telecommunications and storage systems. It generally includes redundant or backup power supplies, redundant data communications connections, environmental controls (e.g., air conditioning, fire suppression) and various security devices. A large data center can consume significant amount of electricity. Most of the equipment is often in the form of server computers (“servers”) mounted in rack cabinets (“racks”), which are usually placed in multiple rows. Different types of racks consume different amounts of resources. For example, a first type of rack can consume 4 Kilo Watts (KW) of power supply, 5 units of airflow, 2 cubic feet per minute (CFM) of cooling, 10 Gigabits per second (Gbps) of network traffic, a second rack type can consume 2 KW of power supply, 3 units of airflow, 4 CFM of cooling, 7 Gbps of network traffic, and so on.

If the racks are not deployed in an appropriate manner, the resource utilization in the data center may not be uniform. Such an imbalance in resource utilization can cause a failure or increase the likelihood of a failure of one or more servers. For example, if a total power supply available for a row is 50 KW and all high power consumption rack types are deployed in the row, whose power consumption is likely to exceed 50 KW, then a power breaker of the row may be triggered causing the racks in the row to lose power. In another example, if all high heat generating racks are placed in a row where there is no sufficient airflow, excessive heat may cause failures in the rack. Accordingly, if the racks are not deployed in appropriate manner, the resource utilization across the data center may be imbalanced, which can cause a failure or increase the likelihood of a failure of the servers in the data center.

### BRIEF DESCRIPTION OF THE DRAWINGS

FIG. 1 is a block diagram illustrating an environment in which the disclosed embodiments can be implemented.

FIG. 2 is a block diagram of an example arrangement of server racks in a data center, consistent with various embodiments.

FIG. 3 is a block diagram of an example for deploying application services on the server racks in the data center, consistent with various embodiments.

FIG. 4 is a block diagram of a server of FIG. 1, consistent with various embodiments.

FIG. 5 is a flow diagram of a process for generating a deployment layout for assigning server racks of various rack types across multiple rows of the data center, consistent with various embodiments.

FIG. 6 is a flow diagram of a process for distributing application services across racks in the data center, consistent with various embodiments.

FIG. 7 is a block diagram of a computer system as may be used to implement features of the disclosed embodiments.

### DETAILED DESCRIPTION

Embodiments are directed to placement of server racks of different types in a data center for efficient allocation of resources to the servers. A data center has limited physical resources (e.g., electrical power, cooling, airflow, network bandwidth, weight capacity, etc.). Various server rack types (e.g., hosting a type of a server computer) consume different amounts of these resources. If the distribution of server rack types in a data center is imbalanced, various unexpected failures can occur. Embodiments consider resource utilizations of all server rack types and generate a deployment layout that assigns these server rack types across multiple rows of the data center to ensure a deployment constraint of the data center is satisfied. For example, a deployment constraint for an efficient allocation of the resources can be that within every row of server racks, a percentage of a total available power supply consumed be substantially constant. For example, if in a first row 80% of the available 100 KW of power supply is consumed by the various types of server racks, then in a second row that has 50 KW of power supply available, the server racks of various types are to be deployed such that be 80% of the 50 KW power supply is consumed. One way to achieve the above resource utilization is that the deployment constraint can be further defined such that within every row of server racks, the percentage of each server rack type is substantially constant. For example, if 10% of a first row has a first server rack type, then 10% of a second row has first server rack type, etc. What is determined as substantially constant can be configured, e.g., by an administrator. For example, if the difference between two percentages is within a specified range, e.g., 2-3%, then the two percentages can be considered to be substantially equal or substantially constant.

After the server racks are deployed, e.g., based on the deployment layout determined as described above, application services that are run on these server racks can also be distributed across specific server racks, e.g., based on resource consumption of the application services. The application services can be bucketed or categorized into various categories or buckets based on their resource consumption. Application services from each bucket are distributed in a similar manner as the server rack types across the data center.

In some embodiments, a server rack (“rack”) is a framework in which multiple server computers (“server”) are installed. The rack contains multiple mounting slots using which the multiple servers can be stacked one above the other, consolidating network resources and minimizing the required floor space. In some embodiments, in a rack filled with multiple servers, a cooling system may be necessary to prevent excessive heat buildup that would otherwise occur when many power-dissipating components are confined in a small space. Note that the term server rack can also be used to refer to servers in the rack, and a rack type to refer to type of the servers in the rack.

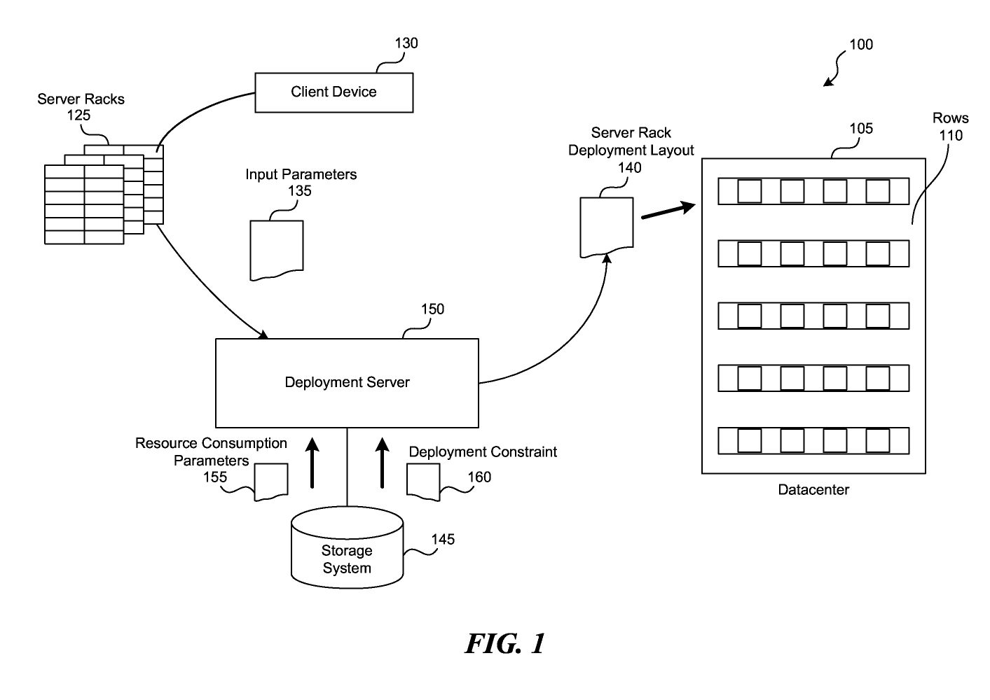

Turning now to figures, FIG. 1 is a block diagram illustrating an environment 100 in which the disclosed embodiments can be implemented. The environment 100 includes a deployment server 150 that can be used to generate a deployment layout 140 for arranging racks 125 in a data center 105. Each of the racks 125 can include one or more servers. The racks 125 can be of various rack types, and different rack types can consume different amount of resources. The resource consumption of a specified rack type is indicated by resource consumption parameters 155 of the specified rack type. Examples of the resource consumption parameters 155 include a power supply consumed by the rack, airflow consumed by the rack, cooling units consumed by the rack, network traffic consumed by the rack, weight of the rack, etc. For example, a first rack type can consume 4 Kilo Watts (KW) of power supply, 5 units of airflow, 2 cubic feet per minute (CFM) of cooling, 10 Gigabits per second (Gbps) of network traffic, a second rack type can consume 2 KW of power supply, 3 units of airflow, 4 CFM of cooling, 7 Gbps of network traffic, a third rack type can consume 4 KW of power supply, 5 units of airflow, 4 CFM of cooling, 7 Gbps of network traffic, and so on. In order for the resource utilization to be uniform, the different types of racks have to be arranged in the data center 105 in a specific manner so that the resource consumption is not imbalanced, which otherwise can cause or increase the likelihood of failures.

The deployment server 150 can generate a recommendation, e.g., the deployment layout 140, for arranging the racks 125 in a specific manner so that the resource utilization is balanced in the data center 105. The deployment layout 140 typically assigns the racks 125 of various types across multiple rows 110 of the data center 105 to ensure a deployment constraint 160 of the data center 105 is satisfied. In some embodiments, the deployment constraint 160 is a condition that may have to be satisfied in order for the resource utilization to be balanced across the data center 105. For example, the deployment constraint 160 can be that in every row of the data center a percentage of a row's total available power supply consumed by the racks in that row should be substantially constant across the rows 110. The deployment layout 140 typically includes the types of racks and the number of racks of each type to be placed in a row for every row of the data center 105.

The input parameters 135 considered by the deployment server 150 for generating the deployment layout 140 can include the rack types and a number of racks of each rack type to be deployed in the data center 105. The input parameters 135 may be sent to the deployment server 150 by a user, e.g., an administrator of the data center 105, using a client device 130. For example, upon receiving a request from the client device 130 for generating a deployment layout, the deployment server 150 can generate a graphical user interface (GUI) at the client device using which the user can input the input parameters 135. The deployment server 150 can retrieve the resource consumption parameters 155 associated with each of the rack types and the deployment constraint 160 from a storage system 145. The deployment server 150 can then generate the deployment layout 140 based on the input parameters 135, the resource consumption parameters 155 of the rack types and the deployment constraint 160.

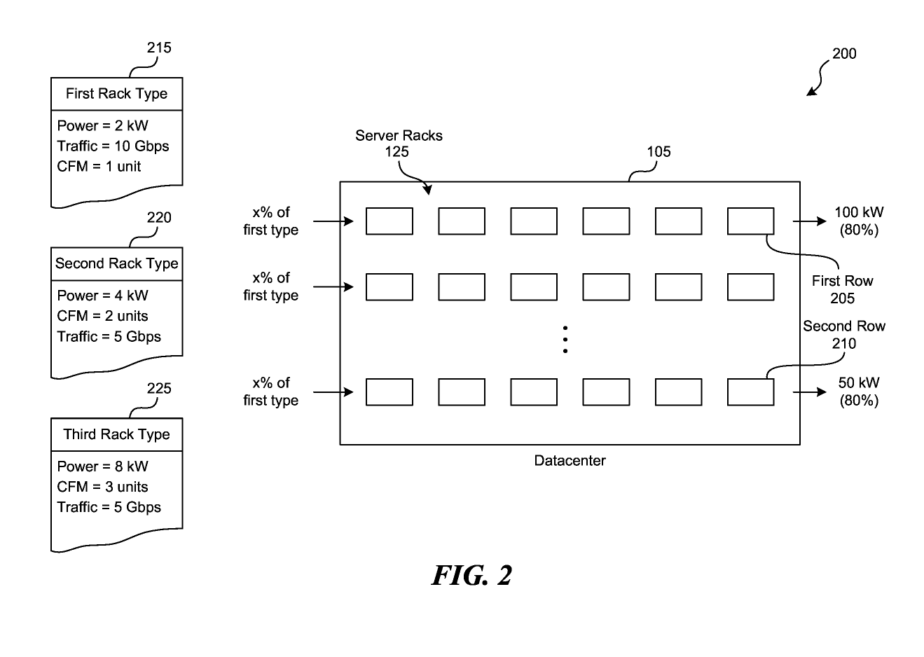

FIG. 2 is a block diagram of an example arrangement 200 of server racks in a data center, consistent with various embodiments. Consider that the deployment constraint 160 indicates that in every row of the data center 105 a percentage of a row's total available power supply consumed by the racks in that row should be substantially constant across the rows 110. Further, the deployment constraint 160 can also specify the power supply available in each of the rows 110. For example, the deployment constraint 160 can specify that the power supply available in a first row is 100 KW and in a second row is 50 KW. Accordingly, based on the deployment constraint 160 the racks have to be deployed in the data center 105 in a way such that if the consumption of the power supply by the racks in the first row 205 reaches 80% (80% of 100 KW), then the power supply consumption by the racks in the second row 210 should also be substantially equal to 80% (80% of 50 KW), that is, the power consumption is relatively balanced across the rows (e.g., regardless of the absolute values of the power consumed in each of the rows). One way to achieve the above results would be to have substantially equal percentage of racks of a specified rack type in each of the rows 110. The deployment constraint 160 can be further defined to indicate that a percentage of racks of a specified rack type in each of the rows 110 are to be substantially equal. For example, if the first row 205 has a total of 20 racks out of which 5 racks are of first type, which is “25%,” then each of the others rows 110 should also have substantially equal percentage, e.g., 25%, of the first type racks. That is, if the second row 210 has 8 racks, then the number of first type racks to be deployed in the second row 210 is to 25% of 8, which is 2 racks.

In some embodiments, the deployment server 150 can employ various algorithms to generate the deployment layout 140, e.g., determine the number of racks of each type to be deployed in a row of the data center 105, based on the deployment constraint 160 and the resource consumption parameters 155. For example, consider that a first rack type 215 can consume 2 KW of power supply, 1 CFM of cooling, 10 Gbps of network traffic, a second rack type 220 can consume 4 KW of power supply, 2 CFM of cooling, 5 Gbps of network traffic, and a third rack type 225 can consume 8 KW of power supply, 3 CFM of cooling, and 5 Gbps of network traffic. Further, consider that the maximum available power supply in the first row is 100 KW. In one example, in generating the deployment layout 140, the deployment server 150 can employ an algorithm to determine a combination of rack servers of the three types to be deployed in the first row 205 such that a total power supply consumed by the combination of rack servers does not exceed 100 KW. The deployment server 150 can arrive at the number of racks considering all necessary inputs, e.g., a total number of racks requested, number of racks of each rack type, number of rows, number of racks per row, power supply for each row and resource consumption parameters of various rack types. Assuming that the deployment server 150 arrives at a, b and c numbers of racks of the three types, respectively, then the deployment server 150 determines a percentage of the first rack type 215 is x % ((a/a+b+c)*100). The deployment server 150 can then determine that other rows of the data center 105 should also have the first type rack as x % of the total number of racks in the corresponding row.

Note that the deployment layout 140 generated in the above example, considers power supply as one of the deployment constraints 160 so that power consumption by the server racks is balanced across the data center 105. In some embodiments, the deployment constraint 160 can consider other resource consumption parameters instead of or in addition to the power supply parameter so that the consumption of one or more resources is balanced across the data center 105.

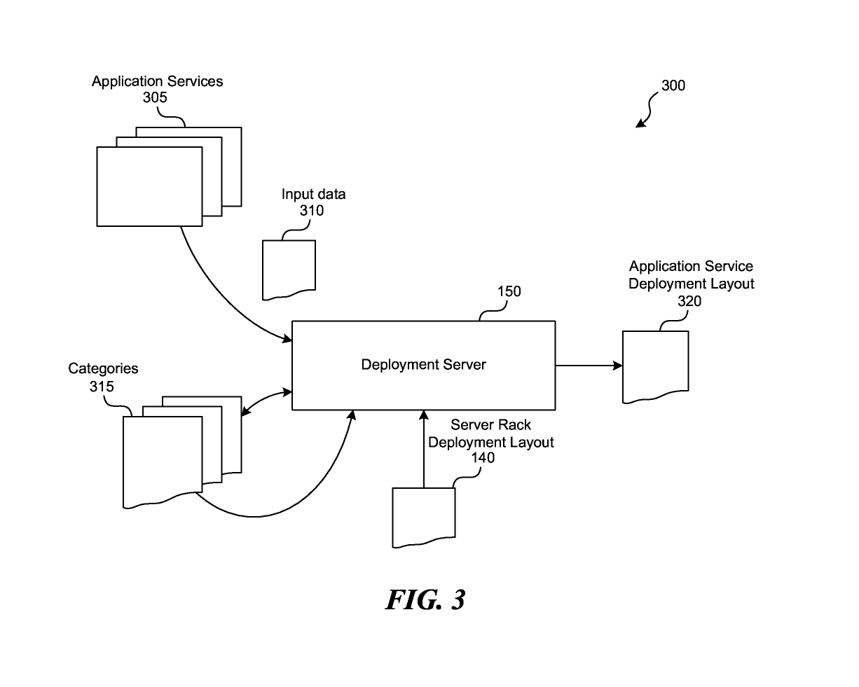

FIG. 3 is a block diagram of an example 300 for deploying application services on the racks in the data center, consistent with various embodiments. The racks 125, or servers in the racks 125, are consumed by various application services 305, e.g., social networking application services, that run on the servers. Examples of application services 305 include a social networking application, a messaging application, an ads-publishing application, a photo management application, a gaming application, etc. Different application services 305 can consume different amount of resources, e.g., power supply, network traffic, airflow, cooling, etc. For example, some application services can consume high power supply and some can consume low power supply. In another example, some application services generate and/or consume high network traffic, whereas some consume low network traffic. In another example, some application services require high cooling, whereas some require low cooling. Accordingly, the application services have to be deployed or distributed to the server racks in a specific manner if the resource consumption is to be balanced across the data center 105.

The application services can be associated with resource consumption indicators, which indicate a level of consumption of a specified resource. For example, resource consumption indicators for power consumption can be “high power” and “low power.” Similarly, the resource consumption indicators for network traffic can be “high traffic” and “low traffic.” Note that the level of consumption of a specified resource in the above examples is represented using two values “high” and “low.” However, the level of consumption can be indicated in various other ways, e.g., as a range, more than two values, etc.

A user can input information such as application identification (ID) of the application services 305, rack type required for the application services 305, resource consumption indicators associated with the application services 305, etc. as input data 310. The deployment server 150 categorizes the application services 305 based on the resource consumption indicators of the application services 305 into multiple categories 315 in which each category is a characteristic of a level of consumption of a specified resource. For example, consider that the user has requested a first rack type 215 for the application services 305, and consider that the categories 315 are “high power,” “high traffic,” “low traffic,” “high CFM,” and “low airflow.” The deployment server 150 analyzes the resource consumption indicators of each of the application services 305 and categorizes the corresponding application service into one of the categories 315 based on the matching resource consumption indicator of the corresponding application service. For example, a first application service that is associated with a “high power” resource consumption indicator is categorized into the “high power” category. After each of the application services 305 is categorized into one of the categories 315, the deployment server 150 generates an application deployment layout 320 based on a distribution criterion to assign the application services from each of the categories 315 to racks of the first rack type 215 deployed in different rows. In some embodiments, the deployment server 150 assigns the application services from each of the categories 315 to different rows of the first rack type 215 racks in a manner similar to the deployment of the racks 125 in the data center 105. The deployment server 150 identifies the racks of the first rack type 215 in the data center 105 based on the deployment layout 140 and distributes the application services from each of the categories 315 based on the distribution criterion. For example, the distribution criterion can indicate that within every row that has the first rack type 215, a percentage of application services hosted by the first rack type 215 that are from a specified category should be substantially constant. For example, if 20% of the application services hosted by the first rack type 215 in the first row 205 are from a “high power” category, then the percentage of the application services hosted by the first rack type 215 in the second row 210 from the “high power” category should also be substantially equal to 20% of all the application services hosted by the first rack type 215 in the second row 210.

In another embodiment, the distribution criterion can indicate that the deployment server 150 is to distribute substantially equal percentage of the application services from a category across the multiple rows in which racks of the first rack type 215 are deployed. For example, if the racks of the first rack type 215 there are deployed in five rows, then each of the five rows hosts 20% of the application services from a specified category. The deployment server 150 continues to distribute application services from each of the categories 315 in the above described manner.

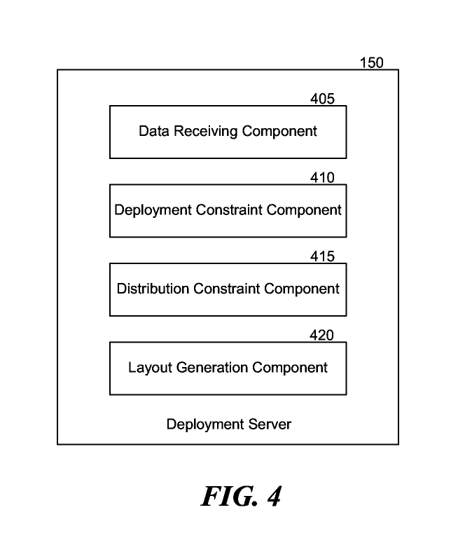

FIG. 4 is a block diagram of the deployment server 150 of FIG. 1, consistent with various embodiments. The deployment server 150 includes a data receiving component 405 that receives input parameters 135 for generating a deployment layout 140 to deploy the racks 125 in a data center 105. The data receiving component 405 can also receive input data 310 for generating an application deployment layout 320, which can be used to assign application services 305 to racks in the data center 105.

The deployment server 150 includes a deployment constraint component 410 that can be used to retrieve, define, and/or customize the deployment constraint 160, which can be used as a constraint in determining the deployment of the racks 125 in the data center 105.

The deployment server 150 includes a distribution constraint component 415 that can be used to retrieve, define, and/or customize the distribution constraint, which can be used as a constraint in determining the distribution of application services 305 to the racks 125 in the data center 105.

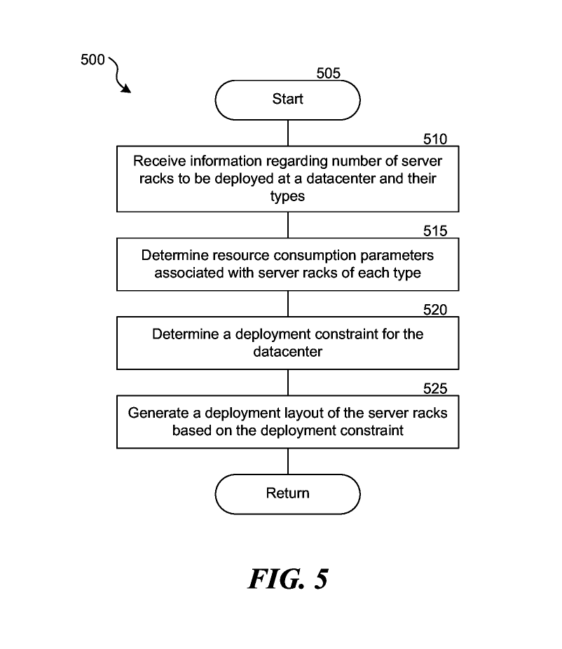

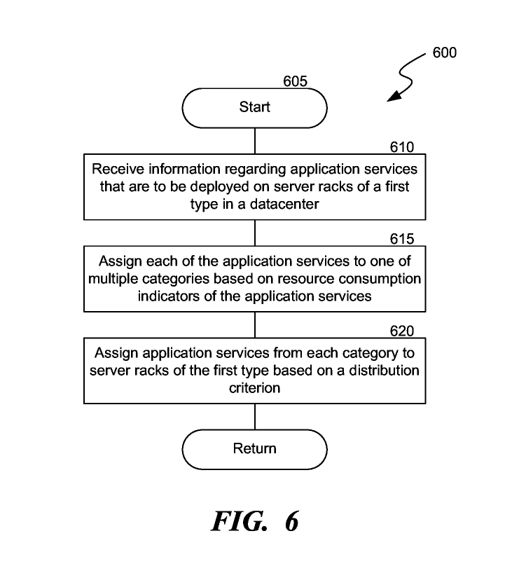

The deployment server 150 includes a layout generation component 420 that can be used to generate a deployment layout 140, which assigns the racks 125 of different types across multiple rows in the data center 105 ensuring that a deployment constraint is satisfied. The layout generation component 420 can also be used to generate the application deployment layout 320, which can be used to distribute application services 305 across specific server racks, e.g., based on resource consumption of the application services 305, so that the resource consumption by the application services 305 is balanced or uniform across the data center. Additional details with respect to the above components are described at least with reference to FIGS. 5 and 6 below.

FIG. 5 is a flow diagram of a process 500 for generating a deployment layout for assigning racks of various rack types across multiple rows of a data center, consistent with various embodiments. The process 500 may be executed in the environment 100 of FIG. 1. The process 500 begins at block 505, and at block 510, the data receiving component 405 receives input parameters for generating a deployment layout, which is used to assign racks of various types across multiple rows of a data center. The input parameters, e.g., input parameters 135, can include information regarding the rack types and a number of racks of each rack type to be deployed in the data center 105.

At block 515, the data receiving component 405 retrieves the resource consumption parameters for each of the rack types, e.g., rack type specified in the input parameters, from a storage system associated with the deployment server 150. Examples of the resource consumption parameters 155 include a power supply consumed by the rack, airflow consumed by the rack, cooling units consumed by the rack, network traffic consumed by the rack, weight of the rack, etc. Different rack types can consume different amounts of the resources.

At block 520, the deployment constraint component 410 retrieves the deployment constraint, e.g., as described at least with reference to FIGS. 1 and 2, that has to be satisfied in deploying the racks 125. As described above at least with reference to FIGS. 1 and 2, in some embodiments, the deployment constraint 160 is a condition that may have to be satisfied in order for the resource utilization to be balanced across the data center 105. For example, the deployment constraint 160 can be that in every row of the data center 105 a percentage of a row's total available power supply consumed by the racks in that row should be substantially constant across the rows 110.

At block 525, the layout generation component 420 generates the deployment layout 140 based on the deployment constraint 160, e.g., as described above at least with reference to FIGS. 1 and 2. The deployment layout 140 typically includes the types of racks and the number of racks of each type to be placed in a row for every row of the data center 105.

FIG. 6 is a flow diagram of a process 600 for distributing application services across racks in a data center, consistent with various embodiments. The process 600 may be executed in the environment 100 of FIG. 1. The process 600 begins at block 605, and at block 610, the data receiving component 405 receives input data, e.g., input data 310, for generating the application service deployment layout, which identifies which application services are to be deployed at which racks of a specified rack type in a data center. The input data 310 can include information regarding application services 305, such as application service IDs and resource consumption indicators of the application services 305.

At block 615, the layout generation component 420 assigns each of the application services 305 to one of the multiple categories 315 based on the resource consumption indicators of the application services 305, e.g., as described at least with reference to FIG. 3.

At block 620, the layout generation component 420 then assigns the application services from each of the categories 315 to various racks of a specified type based on a distribution criterion, e.g., as described at least with reference to FIG. 3. For example, the distribution criterion can indicate that within every row that has the first rack type 215, a percentage of application services hosted by the first rack type 215 that are from a specified category should be substantially constant. For example, if 20% of the application services hosted by the first rack type 215 in the first row 205 are from a “high power” category, then the percentage of the application services hosted by the first rack type 215 in the second row 210 from the “high power” category should also be substantially equal to 20% of all the application services hosted by the first rack type 215 in the second row 210.

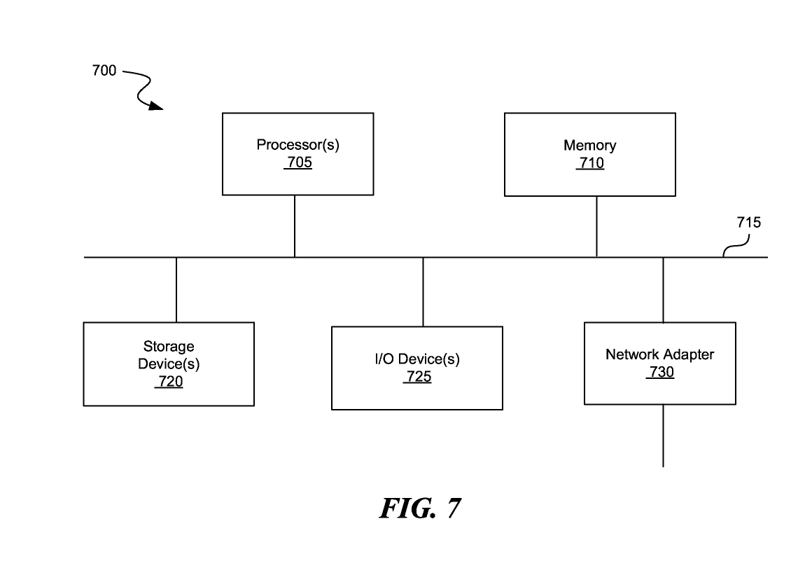

FIG. 7 is a block diagram of a computer system as may be used to implement features of the disclosed embodiments. The computing system 700 may be used to implement any of the entities, components, modules, systems, or services depicted in the examples of the foregoing figures (and any other entities described in this specification). The computing system 700 may include one or more central processing units (“processors”) 705, memory 710, input/output devices 725 (e.g., keyboard and pointing devices, display devices), storage devices 720 (e.g., disk drives), and network adapters 730 (e.g., network interfaces) that are connected to an interconnect 715. The interconnect 715 is illustrated as an abstraction that represents any one or more separate physical buses, point to point connections, or both connected by appropriate bridges, adapters, or controllers. The interconnect 715, therefore, may include, for example, a system bus, a Peripheral Component Interconnect (PCI) bus or PCI-Express bus, a HyperTransport or industry standard architecture (ISA) bus, a small computer system interface (SCSI) bus, a universal serial bus (USB), IIC (I2C) bus, or an Institute of Electrical and Electronics Engineers (IEEE) standard 1394 bus, also called “Firewire”.

The memory 710 and storage devices 720 are computer-readable storage media that may store instructions that implement at least portions of the described embodiments. In addition, the data structures and message structures may be stored or transmitted via a data transmission medium, such as a signal on a communications link. Various communications links may be used, such as the Internet, a local area network, a wide area network, or a point-to-point dial-up connection. Thus, computer readable media can include computer-readable storage media (e.g., “non-transitory” media).

The instructions stored in memory 710 can be implemented as software and/or firmware to program the processor(s) 705 to carry out actions described above. In some embodiments, such software or firmware may be initially provided to the processing system 700 by downloading it from a remote system through the computing system 700 (e.g., via network adapter 730).

The embodiments introduced herein can be implemented by, for example, programmable circuitry (e.g., one or more microprocessors) programmed with software and/or firmware, or entirely in special-purpose hardwired (non-programmable) circuitry, or in a combination of such forms. Special-purpose hardwired circuitry may be in the form of, for example, one or more ASICs, PLDs, FPGAs, etc.

### Remarks

The above description and drawings are illustrative and are not to be construed as limiting. Numerous specific details are described to provide a thorough understanding of the disclosure. However, in some instances, well-known details are not described in order to avoid obscuring the description. Further, various modifications may be made without deviating from the scope of the embodiments. Accordingly, the embodiments are not limited except as by the appended claims.

Reference in this specification to “one embodiment” or “an embodiment” means that a specified feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

The terms used in this specification generally have their ordinary meanings in the art, within the context of the disclosure, and in the specific context where each term is used. Terms that are used to describe the disclosure are discussed below, or elsewhere in the specification, to provide additional guidance to the practitioner regarding the description of the disclosure. For convenience, some terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. One will recognize that “memory” is one form of a “storage” and that the terms may on occasion be used interchangeably.

Consequently, alternative language and synonyms may be used for any one or more of the terms discussed herein, nor is any special significance to be placed upon whether or not a term is elaborated or discussed herein. Synonyms for some terms are provided. A recital of one or more synonyms does not exclude the use of other synonyms. The use of examples anywhere in this specification including examples of any term discussed herein is illustrative only, and is not intended to further limit the scope and meaning of the disclosure or of any exemplified term. Likewise, the disclosure is not limited to various embodiments given in this specification.

Those skilled in the art will appreciate that the logic illustrated in each of the flow diagrams discussed above, may be altered in various ways. For example, the order of the logic may be rearranged, substeps may be performed in parallel, illustrated logic may be omitted; other logic may be included, etc.

Without intent to further limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions will control.

I/We claim:

1. A computer-implemented method, comprising:
receiving, at a server computer, information regarding (a) a number of server racks to be deployed at a data center and (b) multiple types of the server racks, wherein each of the server racks includes multiple server computers;
determining, at the server computer, multiple resource consumption parameters associated with the multiple types, wherein a first type of server rack has server computers having a first set of resource consumption parameters and a second type of server rack has server computers having a second set of resource consumption parameters, the second set of resource consumption parameters distinct from the first set of resource consumption parameters;
determining, at the server computer, a deployment constraint for the data center, the deployment constraint enabling an uniform consumption of one or more of multiple resources across the server racks in the data center; and
generating, at the server computer and based on the deployment constraint, a deployment layout of the server racks, the deployment layout representing an arrangement of the server racks in multiple rows that satisfies the deployment constraint.

2. The computer-implemented method of claim 1, wherein generating the deployment layout includes:
assigning a specified number of a specified type of server racks across the multiple rows of server racks in the data center, wherein a percentage of server racks of the specified type in a row is substantially constant across the multiple rows.

3. The computer-implemented method of claim 1, wherein one of the multiple resource consumption parameters includes at least one of (a) a power supply rating of a specified type of a server rack, (b) an airflow rating of the specified type, (c) a cooling capacity of the specified type, (d) a network traffic bandwidth capacity of the specified type, or (e) a weight of the specified type.

4. The computer-implemented method of claim 1, wherein determining the deployment constraint includes determining that a percentage of an available amount of a resource consumed by server racks in a row of the multiple rows is relatively constant across the multiple rows.

5. The computer-implemented method of claim 4, wherein determining that the percentage of the available amount of the resource consumed is relatively constant across the multiple rows includes:
determining a first percentage of a first amount of a specified resource consumed by server racks in a first row, the first amount being an amount of the specified resource available for the first row,
determining a second percentage of a second amount of the specified resource consumed by server racks in a second row, the second amount being an amount of the specified resource available for the second row, and
determining that the first percentage is substantially equivalent to the second percentage.

6. The computer-implemented method of claim 5, wherein the first percentage corresponds to a percentage of power supply consumed by the server racks in the first row and the second percentage corresponds to a percentage of power supply consumed by the server racks in the second row.

7. The computer-implemented method of claim 1, wherein determining the deployment constraint includes:
determining a total amount of a specified resource available for a first row of the multiple rows, and
determining that the amount of the specified resource consumed by a number of server racks to be deployed should not exceed a threshold percentage of the total amount.

8. The computer-implemented method of claim 7, wherein generating the deployment layout includes:
determining a first number of a first type of server racks and a second number of second type of server racks to be deployed in the first row, wherein a total of resource consumption parameter values of the first number of server racks and the second number of server racks does not exceed the threshold percentage, and
assigning the first number of server racks and the second number of server racks to the first row.

9. The computer-implemented method of claim 8 further comprising:
determining a first percentage of the first type of server racks in the first row, and
assigning a third number of the first type of server racks to a second row of the multiple rows, wherein the third number forms a second percentage of the first type of server racks in the second row, wherein the second percentage is substantially equivalent to the first percentage.

10. The computer-implemented method of claim 1 further comprising:
generating an application deployment layout for assigning multiple application services that are to be deployed on the first type of server rack, the application deployment layout identifying a specified server rack among multiple server racks of the first type to which a first application service of the multiple application services is to be assigned.

11. The computer-implemented method of claim 10, wherein each of the application services is associated with multiple resource consumption indicators, which are indicative of a level of consumption of one or more resources by the application services.

12. The computer-implemented method of claim 11, wherein the one or more resources include at least one of (a) a power consumption of an application service, (b) an airflow rating of the application service, (c) a cooling capacity required for the application service, or (d) network traffic consumption.

13. The computer-implemented method of claim 11, wherein the multiple resource consumption indicators include any of high power, low power, high traffic, low traffic, high airflow, or low airflow.

14. The computer-implemented method of claim 10, wherein generating the application deployment layout includes:
assigning the application services to multiple categories for the first type of server rack, wherein a category of the categories is characterized by a level of consumption of a specified resource by the corresponding application services, and
assigning, based on a distribution criterion, a set of application services from a specified category of the categories to a set of server racks of the first type.

15. The computer-implemented method of claim 14, wherein assigning the set of application services based on the distribution criterion includes:
determining that a number of application services of the specified category to be distributed across the multiple rows of the set of server racks of the first type is to be substantially equal, the determining further including:
assigning a first percentage of the application services from the specified category to server racks of the first type in a first row of the multiple rows and a second percentage of the application services from the specified category to server racks of the first type in a second row of the multiple rows, wherein the first percentage is substantially equal to the second percentage.

16. The computer-implemented method of claim 1 further comprising:
determining that the deployment constraint or one or more of the multiple resource consumption parameters of one or more of the multiple server racks have changed; and
generating a revised deployment layout based on the changed deployment constraint or the one or more of the multiple resource consumption parameters of the one or more the multiple server racks.

17. A computer-readable storage medium storing computer-readable instructions, comprising:
instructions for receiving, at a server computing system, information regarding multiple application services that are to be deployed on multiple server racks of a first type in a data center, wherein the data center includes server racks of the first type arranged in multiple rows, wherein the information includes multiple resource consumption indicators of the multiple application services, which are indicative of a level of consumption of one or more resources by the application services;
instructions for assigning the application services to multiple categories, wherein a category of the categories includes those of the application services that have a same level of consumption of a specified resource; and
instructions for assigning, based on a distribution criterion, a set of application services from a specified category of the categories to a set of server racks of the first type.

18. The computer-readable storage medium of claim 17, wherein the instructions for assigning the set of application services include:
instructions for determining that a number of application services of the specified category to be distributed across the multiple rows of the set of server racks of the first type is to be substantially equal, wherein the instructions for determining further include:
instructions for assigning a first percentage of the application services from the specified category to server racks of the first type in a first row of the multiple rows and a second percentage of the application services from the specified category to server racks of the first type in a second row of the multiple rows, wherein the first percentage is substantially equal to the second percentage.

19. The computer-readable storage medium of claim 17, wherein the multiple resource consumption indicators include any of high power, low power, high traffic, low traffic, high airflow, or low airflow associated with the application services.

20. A system, comprising:
a processor;
a first component configured to receive information regarding (a) a number of server racks to be deployed at a data center and (b) multiple types of the server racks, wherein each of the server racks includes multiple server computers;
a second component configured to determine multiple resource consumption parameters associated with the multiple types, wherein a first type of server rack has server computers having a first set of resource consumption parameters and a second type of server rack has server computers having a second set of resource consumption parameters, the second set of resource consumption parameters distinct from the first set of resource consumption parameters; and
a third component configured to determine a deployment constraint for the data center, the deployment constraint enabling uniform consumption of one or more of multiple resources across the server racks in the data center; and
a fourth component configured to generate, based on the deployment constraint, a deployment layout of the server racks, the deployment layout representing an arrangement of the server racks in multiple rows that satisfies the deployment constraint.
